(19) United States
(12) Patent Application Publication
(10) Pub. No.: US 2012/0280406 A1
(43) Pub. Date: Nov. 8, 2012

(54) SEMICONDUCTOR DEVICE

(75) Inventor: Shinichi DOMAE, Osaka (JP)

(73) Assignee: Panasonic Corporation, Osaka (JP)

(21) Appl. No.: 13/493,547

(22) Filed: Jun. 11, 2012

Related U.S. Application Data
(63) Continuation of application No. PCT/JP2010/004824, filed on Jul. 29, 2010.

(30) Foreign Application Priority Data
Jan. 14, 2010 (JP) 2010-006050

(51) Int. Cl. H01L 23/52

(52) U.S. Cl. 257/777; 257/E23.141

(57) ABSTRACT

A semiconductor device has a three dimensional multi-chip structure including a plurality of chips stacked one on another. The three dimensional multi-chip structure includes a first chip, and a second chip being adjacent to the first chip on an upper or lower side of the first chip, and larger than the first chip. A through electrode is formed in at least one of the first chip or the second chip. The first chip is electrically connected to the second chip via the through electrode. A resin is provided on a surface of the second chip closer to the first chip in a portion of the second chip located outside the first chip.

### CROSS-REFERENCE TO RELATED APPLICATION

This is a continuation of PCT International Application PCT/JP2010/004828 filed on Jul. 29, 2010, which claims priority to Japanese Patent Application No. 2010-006050 filed on Jan. 14, 2010. The disclosures of these applications including the specifications, the drawings, and the claims are hereby incorporated by reference in their entirety.

### BACKGROUND

The present disclosure relates to semiconductor devices and methods of manufacturing the devices, and more particularly to semiconductor devices having a multilayer of a plurality of chips in different chip forms and methods of manufacturing the devices.

As miniaturization and reduction in the thicknesses of electronic devices progress, further reduction in the thicknesses of semiconductor devices used in the electronic devices have been demanded. Also, the demand for the reduction in the thicknesses of semiconductor devices is further increased in accordance with development in multilayer semiconductor devices formed by stacking a plurality of semiconductor elements in a single package.

Conventional semiconductor devices had a thickness ranging from about 200 to 250 μm. Recently, semiconductor devices with a thickness of about 50 μm have been manufactured, and the thickness is being further reduced.

On the other hand, with reduction in the thicknesses of semiconductor devices, there is a problem such as chipping and cracks in LSI chips. A protective resin has been conventionally used to address the problem (see, for example, Japanese Patent Publication

A method of reinforcing a chip using a conventional protective resin will be described below with reference to FIG. 12.

As shown in FIG. 12, in an LSI chip 1 including on a surface, electrodes 2 on which bumps 3 are mounted. Sidewalls of the LSI chip 1 are covered by a protective resin 4. The surface for mounting the bumps 3 is covered by a protective resin 6. The back surface is covered by a protective resin 5. The protective resin 4 provided on the sidewalls of the LSI chip 1 reduces external force application to the LSI chip 1. This technique particularly protects corners of the chip, thereby reducing chipping and cracks. This results in reduction in defects caused in transportation and mounting of the chip, bad connections in mounting the chip, etc., thereby improving yields and reliability.

### SUMMARY

However, the conventional technique of reinforcing the chip targets a single chip, and is not directly applicable to, for example, a multilayer chip formed by stacking a plurality of chips of different sizes.

In view of this problem, it is an objective of the present disclosure to reduce chipping, cracks, etc. in a multilayer chip formed by stacking a plurality of chips of different sizes.

In order to achieve the objective, the present inventor made the following findings as a result of various studies.

FIGS. 13A and 13B are cross-sectional views illustrating an example multilayer chip formed by stacking a plurality of chips of different sizes.

In the multilayer chip shown in FIG. 13A, a top die 8, which is smaller than a bottom die 7, is mounted on the bottom die 7. In this case, local stress is applied to the portions, which are indicated by•in the figure, of the bottom die (i.e., the larger chip) 7, which are in contact with the ends of the top die (i.e., the smaller chip) 8.

In the multilayer chip shown in FIG. 13B, a middle die 9, which is smaller than the bottom die 7, is mounted on the bottom die 7. The top die 8, which is larger than the middle die 9, is mounted on the middle die 9. In this case, local stress is applied to the portions, which are indicated by•in the figure, of the bottom die (the larger chip) 7, which are in contact with the ends of the middle die (smaller chip) 9, as well as the portions, which are indicated by•in the figure, of the top die (larger chip 8), which are in contact with the ends of the middle die (smaller chip) 9.

As such, local stress, which is different from the stress occurring in a single chip, is caused in a multilayer chip, and thus a technique of reinforcing a multilayer chip in view of the local stress is required.

The present disclosure was made based on the findings. A method of manufacturing a semiconductor device according to the present disclosure includes the steps of: (a) bonding a first chip to a substrate; (b) applying a resin to a periphery of the first chip on the substrate, and curing the resin; (c) dicing the substrate and the resin to form a multi-chip structure including: a second chip formed by dividing the substrate, and being larger than the first chip, the first chip bonded to a top of the second chip, and the resin formed on a surface of the second chip closer to the first chip in a portion of the second chip located outside the first chip.

In the present disclosure, through electrodes may be provided in all or some of the chips forming the three-dimensional multi-chip structure. Each of the through electrodes penetrates at least the substrate of the chip, and may or may not penetrate a device layer formed on the substrate. The device layer generally represents a gate electrode, an insulating film, an interconnect layer, etc., which are formed on or above the substrate.

In the method of manufacturing the semiconductor device according to the present disclosure, the step (b) may include the steps (b1) applying a photosensitive first resin to a periphery of the first chip on the substrate to be spaced apart from the first chip, and curing the first resin, and (b2) applying a second resin to fill a space between the first chip and the first resin, and curing the second resin. In the step (c), the substrate and at least one of the first resin or the second resin may be diced to form the multi-chip structure including the second chip formed by dividing the substrate, and being larger than the first chip, the first chip bonded to the top of the second chip, and the first resin and the second resin formed on the surface of the second chip closer to the first chip in the portion of the second chip located outside the first chip. In this case, the first resin may be applied to have a reverse pattern of the first chip. Alternatively, after applying and curing the first resin, the substrate and the first chip may be bonded together. That is, after applying the first resin to a periphery of a first chip mounting region on the substrate provided with the through electrode to be spaced apart from the mounting region, and curing the first resin, the substrate and the first chip may be bonded together. Alternatively, the cured first resin may have a substantially same thickness as the first chip.

In the method of manufacturing the semiconductor device according to the present disclosure, a first through electrode may be formed in the substrate. A device layer, which includes an electrode pad, may be provided on a surface of the first chip closer to the substrate. The substrate and the first chip may be bonded together so that the first through electrode of the substrate is electrically connected to the electrode pad.

In the method of manufacturing the semiconductor device according to the present disclosure, the resin is applied to cover the first chip.

In the method of manufacturing the semiconductor device according to the present disclosure, a first through electrode may be formed in the substrate. A second through electrode may be formed in the first chip. The resin may be photosensitive. In the step (a), the substrate and the first chip may be bonded together so that the first through electrode may be electrically connected to the second through electrode. The method may further include between the step (b) and the step (c), (d) bonding the first chip bonded to the substrate and a third chip larger than the first chip together. In the step (c), the resin and the substrate may be diced to form the multi-chip structure including the second chip formed by dividing the substrate, and being larger than the first chip and the third chip, the first chip bonded to the top of the second chip, the third chip bonded to the top of the first chip, and the resin formed on the surface of the second chip closer to the first chip in the portion of the second chip located outside the first chip. In this case, the resin may be applied to have a reverse pattern of the first chip. Alternatively, after applying and curing the resin, the substrate and the first chip may be bonded together. That is, after applying the resin to a periphery of a first chip mounting region on the substrate provided with the first through electrode to be spaced apart from the mounting region, and curing the first resin, the substrate and the first chip provided with the second through electrode may be bonded together so that the first through electrode is electrically connected to the second through electrode. The cured resin may have a smaller thickness than the first chip. A device layer, which includes an electrode pad electrically connected to the second through electrode, may be provided on a surface of the first chip closer to the substrate. The substrate and the first chip may be bonded together so that the first through electrode of the substrate is electrically connected to the electrode pad. Alternatively, a device layer, which includes an electrode pad, may be provided on a surface of the third chip closer to the first chip. The first chip and the third chip may be bonded together so that the second through electrode of the first chip is electrically connected to the electrode pad. Alternatively, the resin may be provided on a surface of the third chip closer to the first chip in the portion of the third chip located outside the first chip. In other words, the resin may be interposed between the surface of the second chip closer to the first chip in the portion of the second chip located outside the first chip and the surface of the third chip closer to the first chip in the portion of the third chip located outside the first chip. This reliably reduces local stress application on the portions of the second chip, which are in contact with the ends of the first chip, and the portions of the third chip, which are in contact with the ends of the first chip. The resin may be spaced apart from a side end surface of the first chip. Alternatively, the resin may fill a space surrounded by the side end surface of the first chip, the surface of the second chip closer to the first chip, and the surface of the third chip closer to the first chip.

In the method of manufacturing the semiconductor device according to the present disclosure, the resin may be made of a material selected from the group consisting of polyimide, acrylate monomer, epoxy acrylate, urethane acrylate, polyester acrylate, alicyclic epoxy, vinyl ether, and hybrid monomer.

A semiconductor device according to the present disclosure has a three dimensional multi-chip structure comprising a plurality of chips stacked one on another. The three dimensional multi-chip structure includes a first chip, and a second chip being adjacent to the first chip on an upper or lower side of the first chip, and larger than the first chip. A through electrode is formed in at least one of the first chip or the second chip. The first chip is electrically connected to the second chip via the through electrode. A resin is provided on a surface of the second chip closer to the first chip in a portion of the second chip located outside the first chip.

In the semiconductor device according to the present disclosure, the through electrode may be formed in the second chip. A device layer including an electrode pad is formed on a surface of the first chip closer to the second chip. The first chip and the second chip may be bonded together so that the through electrode of the second chip is electrically connected to the electrode pad.

In the semiconductor device according to the present disclosure, the resin may be formed on an end of the second chip.

In the semiconductor device according to the present disclosure, a side end surface of the resin may be substantially flush with a side end surface of the second chip.

In the semiconductor device according to the present disclosure, the three dimensional multi-chip structure is a double-chip structure of the first chip and the second chip. In this case, the resin may be provided to cover a surface of the first chip opposite to the second chip.

In the semiconductor device according to the present disclosure, the resin may be provided to cover a corner formed by a side end surface of the first chip, and a surface of the second chip closer to the first chip in a portion of the second chip located outside the first chip. This reliably reduces local stress application on the portions of the second chip, which are in contact with the ends of the first chip.

In the semiconductor device according to the present disclosure, the resin may have a substantially same thickness as the first chip.

In the semiconductor device according to the present disclosure, a gap may be formed in at least part of space between the resin and the side end surface of the first chip. In this case, another resin different from the resin may fill the gap.

In the semiconductor device according to the present disclosure, the three dimensional multi-chip structure may further include a third chip being adjacent to the first chip on a surface of the first chip opposite to the second chip, and larger than the first chip. In this case, a first through electrode may be provided in the first chip. A second through electrode may be provided in the second chip. The first chip and the second chip may be bonded together so that the first through electrode is electrically connected to the second through electrode. Alternatively, a device layer, which includes an electrode pad electrically connected to the first through electrode, may be provided on a surface of the first chip closer to the second chip. The first chip and the second chip may be bonded together so that the second through electrode of the second chip is electrically connected to the electrode pad. Alternatively, a device layer, which includes an electrode pad, may be provided on a surface of the third chip closer to the first chip. The first chip and the third chip may be bonded together so that the first through electrode of the first chip is electrically connected to the electrode pad. Alternatively, the resin may be provided in contact with a surface of the third chip closer to the first chip in a portion of the third chip located outside the first chip. In other words, the resin may be interposed between the surface of the second chip closer to the first chip in the portion of the second chip located outside the first chip, and the surface of the third chip closer to the first chip in the portion of the third chip located outside the first chip. This reliably reduces local stress application on the portions of the second chip, which are in contact with the ends of the first chip, and the portions of the third chip, which are in contact with the ends of the first chip. Note that a gap may be formed in at least part of space between the resin and a side end surface of the first chip. In this case, another resin different from the resin may fill the gap. Alternatively, the resin may fill a space surrounded by the side end surface of the first chip, the surface of the second chip closer to the first chip, and the surface of the third chip closer to the first chip.

In the semiconductor device according to the present disclosure, the resin may be made of a material selected from the group consisting of polyimide, acrylate monomer, epoxy acrylate, urethane acrylate, polyester acrylate, alicyclic epoxy, vinyl ether, and hybrid monomer.

According to the present disclosure, in the multi-chip structure including the first chip and the second chip larger than the first chip, the resin is provided on the surface of the second chip closer to the first chip in the portion of the second chip located outside the first chip. This reduces local stress application on the multi-chip structure, for example, local stress application on the portions of the second chip, which are in contact with the ends of the first chip. As a result, a highly reliable semiconductor device with reduced chipping, cracks, etc. can be provided.

As described above, the semiconductor device according to the present disclosure reduces chipping, cracks, etc. of an LSI chip in a multi-chip structure formed by stacking a plurality of chips of different sizes, and is particularly useful for a semiconductor device having a multi-chip structure formed by stacking a plurality of chips in different chip forms.

### BRIEF DESCRIPTION OF THE DRAWINGS

FIG. 1 is a cross-sectional view of a semiconductor device according to a first embodiment.

FIGS. 2A and 2B are respectively a top view and a cross-sectional view illustrating an example where the semiconductor device according to the first embodiment is mounted on a printed-circuit board.

FIGS. 3A-3G are cross-sectional views illustrating steps of a method of manufacturing the semiconductor device according to the first embodiment. FIG. 3H is a top view illustrating the step of FIG. 3D.

FIGS. 4A-4H are cross-sectional views illustrating steps of a method of manufacturing a semiconductor device according to a first variation of the first embodiment.

FIG. 4I is a top view illustrating the step of FIG. 4D. FIG. 4J is a top view illustrating the step of FIG. 4E.

FIGS. 5A-5H are cross-sectional views illustrating steps of a method of manufacturing a semiconductor device according to a second variation of the first embodiment. FIG. 5I is a top view illustrating the step of FIG. 5D. FIG. 5J is a top view illustrating the step of FIG. 5E.

FIG. 6 is a cross-sectional view of a semiconductor device according to a second embodiment.

FIGS. 7A and 7B are respectively a top view and a cross-sectional view illustrating an example where the semiconductor device according to the second embodiment is mounted on a printed-circuit board.

FIGS. 8A-8G are cross-sectional views illustrating steps of a method of manufacturing the semiconductor device according to the second embodiment.

FIGS. 9A and 9B are cross-sectional views illustrating steps of the method of manufacturing the semiconductor device according to the second embodiment. FIG. 9C is a top view corresponding to the cross-sectional view of FIG. 8D. FIG. 9D is a top view corresponding to the cross-sectional view of FIG. 8E.

FIGS. 10A-10G are cross-sectional views illustrating steps of a method of manufacturing a semiconductor device according to a variation of the second embodiment.

FIGS. 11A-11B are cross-sectional views illustrating steps of a method of manufacturing a semiconductor device according to the variation of the second embodiment.

FIG. 11C is a top view corresponding to the cross-sectional view of FIG. 10D. FIG. 11D is a top view corresponding to the cross-sectional view of FIG. 10E.

FIG. 12 is a cross-sectional view of a conventional semiconductor device.

FIGS. 13A and 13B is cross-sectional views illustrating a multilayer chip formed by stacking a plurality of chips of different sizes.

### DETAILED DESCRIPTION

### First Embodiment

A semiconductor device and a method of manufacturing the device according to a first embodiment will be described hereinafter with reference to the drawings.

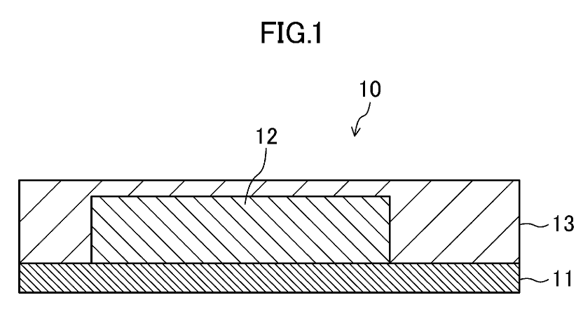

FIG. 1 is a cross-sectional view of the semiconductor device according to the first embodiment, specifically, a semiconductor device having a three-dimensional double-chip structure.

As shown in FIG. 1, a semiconductor device 10 according to the first embodiment includes a logic chip (e.g., a bottom die) 11 having, for example, a chip size of 5 mm×5 mm and a chip thickness of about 20 μm, and a dynamic random access memory (DRAM) chip (e.g., a top die) 12 formed on the bottom die 11 and having, for example, a chip size of 2 mm×3 mm and a chip thickness of about 100 μm.

The present inventor found that local stress is applied to a large chip in a stack of a plurality of chips of different sizes as in the semiconductor device shown in FIG. 1. In particular, in a multi-chip structure of a small chip and a large chip, which are adjacent in the stacking direction, excessive local stress is applied to protrusions of the large chip where the lengths of the protrusions of the large chip from the chip ends of the small chip are greater than the thickness of the large chip.

In this embodiment, a resin 13 made of, for example, polyimide is formed on the surface of the bottom die 11 closer to the top die 12 around the top die 12, i.e., the portion of the bottom die 11 located outside the top die 12. Specifically, the resin 13 is provided on the entire surface of the bottom die 11 closer to the top die 12, from the tops of the ends of the bottom die 11 to the surface of the top die 12 opposite to the bottom die 11. The corner, which is formed by the side end surface of the top die 12 and the surface of the bottom die 11 closer to the top die 12 in the portion of the bottom die 11 located outside the top die 12, is covered by the resin 13. The side end surface of the resin 13 is substantially flush with the side end surface of the bottom die 11.

In this embodiment, the resin 13 is provided in the region without the chip around the chip (i.e., the top die 12) smaller than the adjacent chip (i.e., the bottom die 11). This allows the resin 13 to receive stress applied on the protrusions of the bottom die 11. This reduces local stress application on the bottom die 11, for example, local stress application on the parts the bottom die 11, which are in contact with the ends of the top die 12. As a result, a highly reliable semiconductor device with reduced chipping, cracks, etc. can be provided.

While in this embodiment, an example has been described where a logic chip and a DRAM chip are stacked, the present disclosure is not limited thereto. Where other types of chip with various functions are stacked, advantages similar to those of this embodiment can be provided. In this embodiment, the double-chip structure has been described as an example. Instead, where the multi-chip structure is formed of three or more layers, advantages similar to those of this embodiment can be provided.

While in this embodiment, the resin 13 is provided on the ends of the bottom die 11, the resin 13 may not be provided on the ends of the bottom die 11. While the resin 13 is provided on the surface of the top die 12 opposite to the bottom die 11, the resin 13 may not be provided on the surface of the top die 12 opposite to the bottom die 11. While the corner, which is formed by the side end surface of the top die 12 and the surface of the bottom die 11 closer to the top die 12 in a portion of the bottom die 11 located outside the top die 12, is covered by the resin 13, the corner may not be covered by the resin 13. In other words, the resin 13 may be spaced apart from the side end surfaces of the top die 12. While the resin 13 is provided so that the side end surfaces of the resin 13 are substantially flush with the side end surfaces of the bottom die 11, the resin 13 may be provided so that the side end surfaces of the resin 13 are not flush with the side end surfaces of the bottom die 11.

In this embodiment, the top die (i.e., the smaller chip) 12 and the bottom die (i.e., the larger chip) 11 are stacked so that the smaller chip is adjacent to the larger chip under the smaller chip. Instead, however, where the smaller chip and the larger chip are stacked so that the smaller chip is adjacent to the larger chip on the smaller chip, advantages similar to those of this embodiment can be obtained by providing the resin in the region without the chip around the smaller chip.

While in this embodiment, the resin 13 is made of polyimide, the material is not limited thereto. The resin 13 may be made of, for example, one or more materials selected from the group consisting of polyimide, acrylate monomer, epoxy acrylate, urethane acrylate, polyester acrylate, alicyclic epoxy, vinyl ether, hybrid monomer, etc.

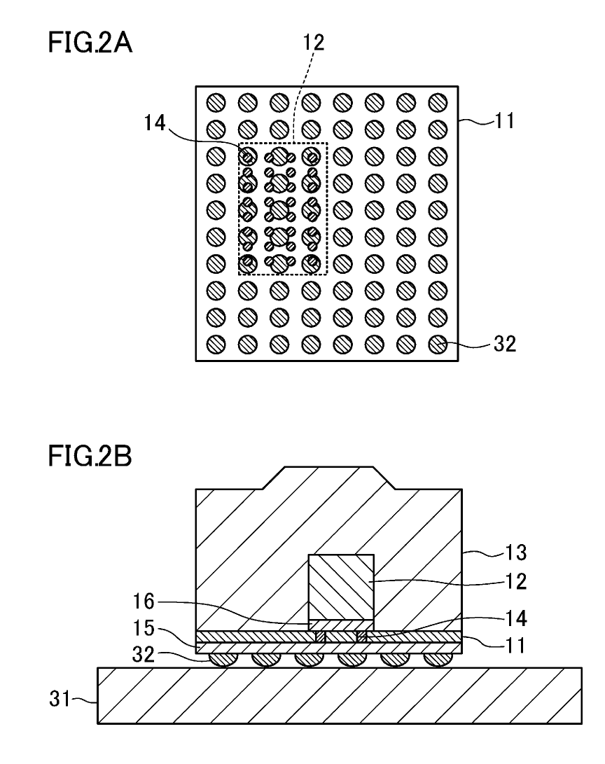

FIGS. 2A and 2B are respectively a top view and a cross-sectional view illustrating an example where a semiconductor device having a multi-chip structure similar to that of this embodiment is mounted on a printed-circuit board. FIG. 2A illustrates the surface of the semiconductor device mounted on the printed-circuit board together with the mounting range of a smaller chip and through electrodes of a larger chip (a device layer is not shown) located in the range. In FIGS. 2A and 2B, the same reference characters as those shown in FIG. 1 are used to represent elements corresponding to the elements of the semiconductor device according to this embodiment.

As shown in FIGS. 2A and 2B, the top die 12 having a small area and a great chip thickness is stacked on the bottom die 11 having a large area and a small chip thickness, thereby forming a double-layer chip. Through electrodes 14 are formed in the bottom die 11. A device layer 15 electrically connected to the through electrodes 14 is provided on the surface of the bottom die 11 opposite to the top die 12. Solder bumps 32 are provided on the surface of the device layer 15 opposite to the bottom die 11. The double-layer chip of the bottom die 11 and the top die 12 are flip-chip mounted on a printed-circuit board 31 with the solder bumps 32 interposed therebetween.

A device layer 16 electrically connected to the through electrodes 14 is provided on the surface of the top die 12 closer to the bottom die 11. The resin 13 is provided on the entire surface of the bottom die 11 closer to the top die 12, from the tops of the ends of the bottom die 11 to the surface of the top die 12 opposite to the bottom die 11. That is, the region on the bottom die 11 without the top die 12 is covered with the resin 13. This enables high-density mounting of a semiconductor device with reduced chipping, cracks, etc.

While in the mounting example shown in FIGS. 2A and 2B, the double-layer chip is flip-chip mounted on the printed-circuit board 31, an interposer (e.g., an interposing substrate), a silicon interposer (e.g., a silicon interposing substrate), etc. may be used in place of the printed-circuit board 31.

A method of manufacturing the semiconductor device according to the first embodiment, and more particularly, a method of manufacturing a semiconductor device having a structure similar to that of the semiconductor device according to the first embodiment shown in FIG. 1 will be described hereinafter with reference to the drawings.

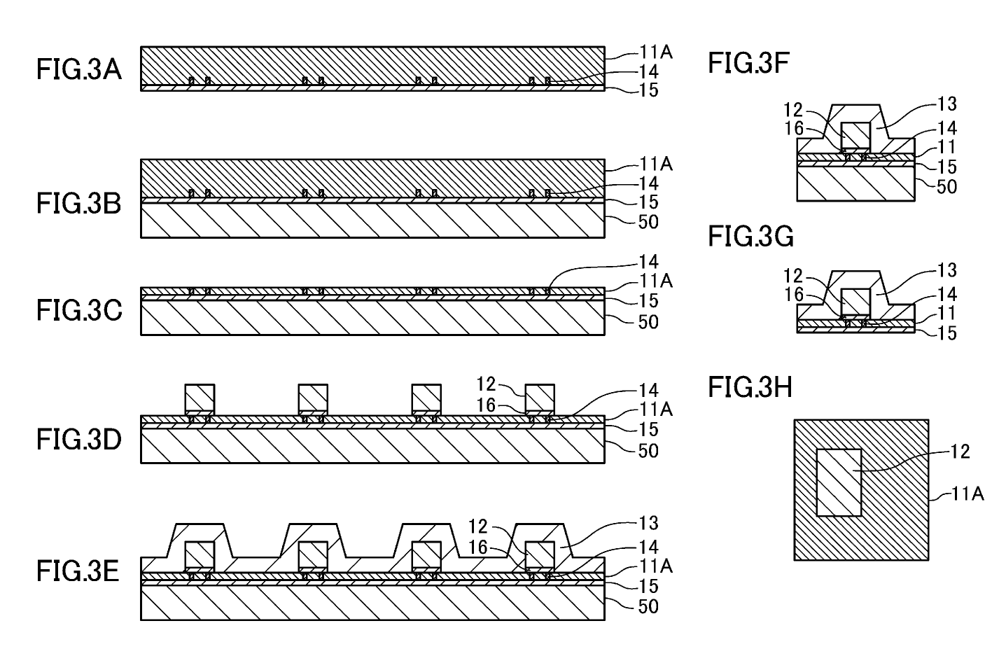

FIGS. 3A-3G are cross-sectional views illustrating steps of the method of manufacturing the semiconductor device according to the first embodiment. FIG. 3H is a top view illustrating the step of FIG. 3D. In FIGS. 3A-3H, the same reference characters as those shown in FIGS. 1, 2A, and 2B are used to represent elements corresponding to the elements of the semiconductor device according to this embodiment.

First, as shown in FIG. 3A, a silicon (Si) wafer 11A is prepared, which includes inside, the through electrodes (hereinafter referred to as through-silicon vias (TSVs)) 14 with a diameter of, e.g., about 5 μm, and includes on one surface, the device layer 15 electrically connected to the TSVs 14.

Next, as shown in FIG. 3B, a carrier 50 is bonded to the one surface of the silicon wafer 11A with the device layer 15 interposed therebetween.

Then, as shown in FIG. 3C, the surface (hereinafter referred to as “the other surface”) of the silicon wafer 11A opposite to the carrier 50 is polished until the TSVs 14 are exposed. The thickness of the silicon wafer 11A after the polishing is, for example, about 20 μm.

After that, as shown in FIG. 3D, the plurality of top dies 12, each of which is processed in a separate chip and includes the device layer 16 on one surface, are bonded to the polished other surface of the silicon wafer 11A with the device layers 16 interposed therebetween. An uppermost layer interconnect (not shown) including an electrode pad is formed on the uppermost surface of the device layer 16. Each of the top dies 12 and the silicon wafer 11A are bonded together so that the electrode pad is electrically connected to the TSV 14 of the silicon wafer 11A. Note that the top dies 12 have a chip thickness of, e.g., about 100 μm. FIG. 3H illustrates that one of the top dies 12 is bonded to the polished other surface of the silicon wafer 11A.

Next, as shown in FIG. 3E, the resin 13 made of, for example, polyimide, is applied on the polished other surface of the silicon wafer 11A to cover the top dies 12 and then cured. The thickness of the resin 13 after the curing is, for example, about 50 μm.

Then, as shown in FIG. 3F, the cured resin 13, the silicon wafer 11A, and the carrier 50 are diced at once, thereby forming a plurality of double-chip structures, one of which is shown in FIG. 3F. Each of the structures includes the bottom die 11 divided from the silicon wafer 11A and being larger than the top die 12, the top die 12 bonded to the top of the bottom die 11, and the resin 13 formed on the bottom die 11 to cover the top die 12.

After that, as shown in FIG. 3G, the carrier 50 bonded to the bottom die 11 of each of the double-chip structures is removed, thereby completing the multilayer chip of the bottom die 11 and the top die 12.

Through the above-described manufacturing process, the resin 13 can be provided in the region without the chip around the chip (i.e., the top die 12) smaller than the adjacent large chip (i.e., the bottom die 11). This structure allows the resin 13 to receive stress applied on the protrusions of the bottom die 11 from the top die 12. This leads to reduction in the local stress application on the bottom die 11, for example, the local stress application on the portions of the bottom die 11, which are in contact with the ends of the top die 12. As a result, a highly reliable semiconductor device with reduced chipping, cracks, etc. can be provided.

In this embodiment, since the resin 13 is scribed and divided into the chips, i.e., scribe lines are opened, dicing damages can be reduced. In particular, a combination of this method and for example, Cu band etching, in which TSVs filled with Cu are etched to open scribe lines, further reduces the damages.

Note that the manufacturing method of this embodiment is advantageous in reducing the manufacturing steps as compared to the other embodiments described below.

While in this embodiment, an example has been described where the other surface (i.e., the surface opposite to the device layer formation surface) of the silicon wafer 11A is bonded to the device layer formation surface of each of the top dies 12, the structure is not limited thereto. The device layer formation surface of the silicon wafer 11A may be bonded to the surface of the top die 12 opposite to the device layer formation surface thereof. Alternatively, the device layer formation surfaces of the silicon wafer 11A and the top die 12, or the surfaces of the silicon wafer 11A and the top die 12 opposite to the device layer formation surfaces thereof may be bonded together.

While in this embodiment, the resin (i.e., the coating material) 13 is made of polyimide, the material is not limited thereto. The resin 13 may be made of, for example, one or more materials selected from the group consisting of polyimide, acrylate monomer, epoxy acrylate, urethane acrylate, polyester acrylate, alicyclic epoxy, vinyl ether, hybrid monomer, etc.

While in this embodiment, the silicon wafer 11A is used as the substrate of the bottom die 11, a substrate made of other materials may be used instead.

While in this embodiment, the resin 13 is applied to cover the top dies 12, the configuration is not limited thereto. As long as the resin 13 is applied around the top dies 12 on the silicon wafer 11A, advantages similar to those in this embodiment can be obtained.

### First Variation of First Embodiment

A method of manufacturing a semiconductor device according to a first variation of the first embodiment, specifically, a method of manufacturing a semiconductor device having a structure similar to that of the semiconductor device according to the first embodiment shown in FIG. 1, will be described hereinafter with reference to the drawings.

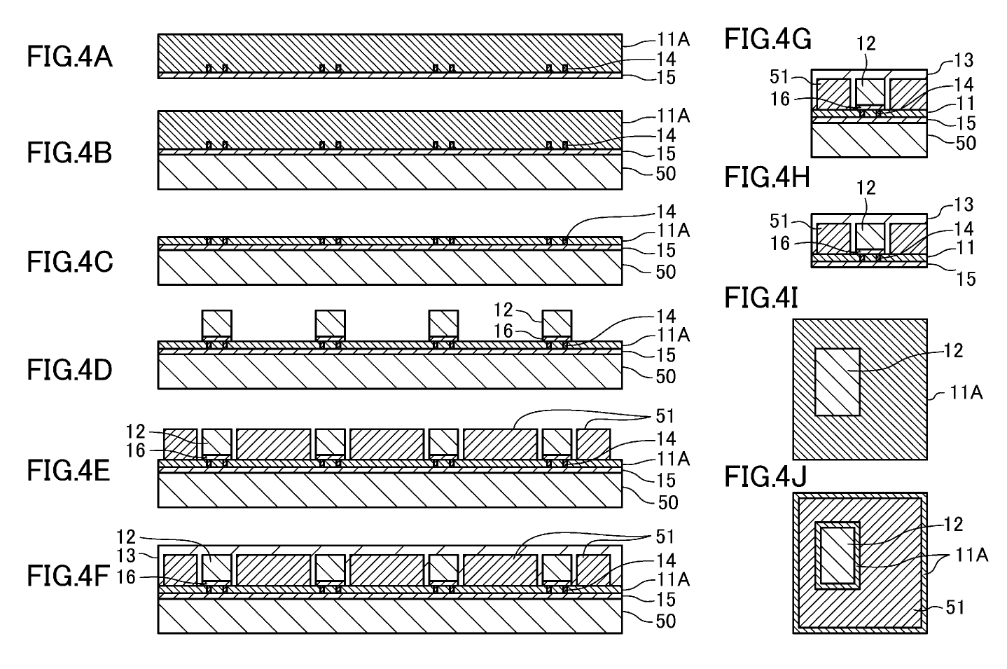

FIGS. 4A-4H are cross-sectional views illustrating steps of the method of manufacturing the semiconductor device according to the first variation of the first embodiment. FIG. 4I is a top view illustrating the step of FIG. 4D. FIG. 4J is a top view illustrating the step of FIG. 4E. In FIGS. 4A-4J, the same reference characters as those shown in FIGS. 1, 2A and 2B are used to represent elements corresponding to the elements of the semiconductor device according to the first embodiment.

Similar to the step shown in FIG. 3A of the first embodiment, as shown in FIG. 4A, a silicon wafer 11A is prepared, which includes insides, TSVs 14 of, e.g., a diameter of about 5 μm, and includes on one surface, a device layer 15 electrically connected to the TSVs 14.

Next, similar to the step shown in FIG. 3B of the first embodiment, as shown in FIG. 4B, a carrier 50 is bonded to the one surface of the silicon wafer 11A with the device layer 15 interposed therebetween.

Then, similar to the step shown in FIG. 3C of the first embodiment, as shown in FIG. 4C, the surface (hereinafter referred to as “the other surface”) of the silicon wafer 11A opposite to the carrier 50 is polished until the TSVs 14 are exposed. The thickness of the silicon wafer 11A after the polishing is, for example, about 20 μm.

After that, similar to the step shown in FIG. 3D of the first embodiment, as shown in FIG. 4D, a plurality of top dies 12, each of which is processed in a separate chip and includes a device layer 16 on one surface, are bonded to the polished other surface of the silicon wafer 11A with the device layers 16 interposed therebetween. An uppermost layer interconnect (not shown) including an electrode pad is formed on the uppermost surface of the device layer 16. Each of the top dies 12 and the silicon wafer 11A are bonded together so that the electrode pad is electrically connected to the TSV 14 of the silicon wafer 11A. Note that the top dies 12 have a chip thickness of, e.g., about 100 μm. FIG. 4I illustrates that one of the top dies 12 is bonded to the polished other surface of the silicon wafer 11A.

Next, as shown in FIG. 4E, a photosensitive resin 51 made of, for example, photosensitive polyimide, is applied around the top dies 12 on the silicon wafer 11A to be spaced apart from the top dies 12, and then the photosensitive resin 51 is cured. The photosensitive resin 51 is applied to have a reverse pattern of the top dies 12. The distance between the photosensitive resin 51 and each of the top dies 12 in the application is, for example, about 100 μm. The thickness of the photosensitive resin 51 after the curing is about 100 μm, which is equal to the chip thickness of the top dies 12. FIG. 4J illustrates that the photosensitive resin 51 is provided around one of the top dies 12 bonded to the silicon wafer 11A.

In this variation, the distance between each of the top dies 12 and the photosensitive resin 51 is set substantially equal to the chip thickness of the top dies 12 for the following reason. If the photosensitive resin 51 is patterned in the form shown in FIG. 4E by exposure and development after applying the photosensitive resin 51 to the entire surface of the silicon wafer 11A including the tops of the top dies 12. Immediately after applying the photosensitive resin 51, the thickness of the photosensitive resin 51 near the top dies 12 becomes great. Thus, in order to make the thickness of the photosensitive resin 51 uniform, the distance between each of the top dies 12 and the photosensitive resin 51 needs to be sufficiently long, e.g., about 100 μm. In FIGS. 4A-4H illustrating the steps of the manufacturing method of this variation, since the sizes in the lateral direction are shown smaller, the distances between the top dies 12 and the photosensitive resin 51 are shown differently from the actual distances.

Next, as shown in FIG. 4F, the resin 13 made of, for example, polyimide, is applied on the polished other surface of the silicon wafer 11A to cover the top dies 12 and the photosensitive resin 51 formed between the adjacent top dies 12, and then cured. As a result, the gap between each of the top dies 12 and the photosensitive resin 51 is filled with the resin 13. The thickness of the resin 13 after the curing is, for example, about 50 μm on the top dies 12 and the photosensitive resin 51.

Then, as shown in FIG. 4G, the cured resin 13, the cured photosensitive resin 51, the silicon wafer 11A, and the carrier 50 are diced at once, thereby forming a plurality of double-chip structures, one of which is shown in FIG. 4G. Each of the structures includes a bottom die 11 divided from the silicon wafer 11A and being larger than a top die 12, the top die 12 bonded to the top of the bottom die 11, the resin 13 formed on the bottom die 11 to cover the top die 12, and the photosensitive resin 51 formed around the top die 12 on the bottom die 11.

After that, as shown in FIG. 4H, the carrier 50 bonded to the bottom die 11 of each of the double-chip structures is removed, thereby completing the multilayer chip of the bottom die 11 and the top die 12.

Through the above-described manufacturing process, the resin 13 and the photosensitive resin 51 can be provided in the region without the chip around the chip (i.e., the top die 12) smaller than the adjacent large chip (i.e., the bottom die 11). This structure allows the resin 13 and the photosensitive resin 51 to receive stress applied on the protrusions of the bottom die 11 from the top die 12. This leads to reduction in the local stress application on the bottom die 11, for example, the local stress application on the portions of the bottom die 11, which are in contact with the ends of the top die 12. As a result, a highly reliable semiconductor device with reduced chipping, cracks, etc. can be provided.

Since the flatness of the surface of the resin 13 can be improved as compared to the first embodiment, this variation is advantageous in further reducing the stress applied on the multi-chip structures.

In this variation, since the photosensitive resin 51 is applied to have the reverse pattern of the top dies 12, the flatness of the resin can be further improved, thereby providing a more highly reliable semiconductor device. This technique is advantageous in stacking three or more layers of chips.

In this variation, since the resin 13 and the photosensitive resin 51 are scribed and divided into the chips, i.e., scribe lines are opened, dicing damages can be reduced. In particular, a combination of this method and for example, Cu band etching, in which TSVs filled with Cu are etched to open scribe lines, further reduces the damages.

While in this variation, an example has been described where the other surface (i.e., the surface opposite to the device layer formation surface) of the silicon wafer 11A is bonded to the device layer formation surface of each of the top dies 12, the structure is not limited thereto. The device layer formation surface of the silicon wafer 11A may be bonded to the surface of the top die 12 opposite to the device layer formation surface thereof. Alternatively, the device layer formation surfaces of the silicon wafer 11A and the top die 12, or the surfaces of the silicon wafer 11A and the top die 12 opposite to the device layer formation surfaces thereof may be bonded together.

While in this variation, the photosensitive resin 51 and the resin (coating material) 13 are made of polyimide, the material is not limited thereto. The photosensitive resin 51 and the resin 13 may be made of, for example, one or more photoresistive materials or coating materials selected from the group consisting of polyimide, acrylate monomer, epoxy acrylate, urethane acrylate, polyester acrylate, alicyclic epoxy, vinyl ether, hybrid monomer, etc.

While in this variation, the silicon wafer 11A is used as the substrate of the bottom die 11, a substrate made of other materials may be used instead.

While in this variation, the resin 13 is applied to cover the top dies 12 and the photosensitive resin 51, the configuration is not limited thereto. As long as the resin 13 is applied to fill the gaps between the top dies 12 and the photosensitive resin 51, advantages similar to those in this variation can be obtained. In this case, in the dicing shown in FIG. 4G, one of the photosensitive resin 51 or the resin 13 is diced together with the silicon wafer 11A and the carrier 50, thereby forming a double-chip structure including the bottom die 11, the top die 12 bonded to the top of the bottom die 11, and the photosensitive resin 51 and the resin 13, which are formed on the surface of the bottom die 11 closer to the top die 12 in the portion of the bottom die 11 located outside the top die 12.

### Second Variation of First Embodiment

A method of manufacturing a semiconductor device according to a second variation of the first embodiment, and more particularly, a method of manufacturing a semiconductor device having a structure similar to that of the semiconductor device according to the first embodiment shown in FIG. 1 will be described hereinafter with reference to the drawings.

This variation differs from the first variation of the first embodiment in the following respect. Specifically, in the first variation of the first embodiment, after the top dies 12 and the silicon wafer 11A are bonded together, the photosensitive resin 51 is formed around the top dies 12 on the silicon wafer 11A. On the other hand, in this variation, after the photosensitive resin is formed around the top die mounting regions on the silicon wafer, the top dies and the silicon wafer are bonded together.

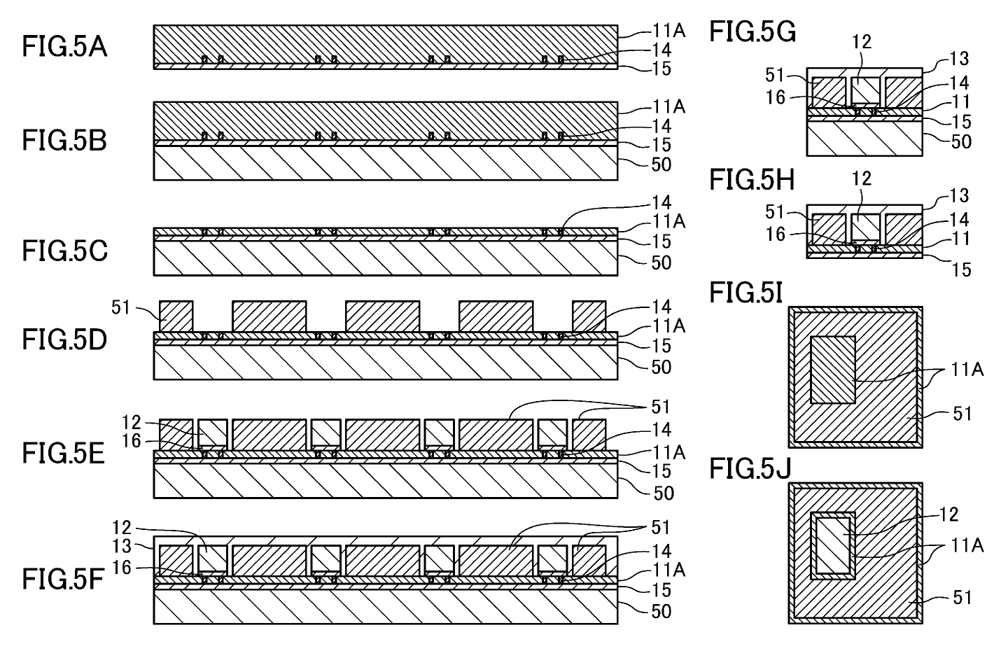

FIGS. 5A-5H are cross-sectional views illustrating steps of the method of manufacturing the semiconductor device according to the second variation of the first embodiment. FIG. 5I is a top view illustrating the step of FIG. 5D. FIG. 5J is a top view illustrating the step of FIG. 5E. In FIGS. 5A-5J, the same reference characters as those shown in FIGS. 1, 2A and 2B are used to represent elements corresponding to the elements of the semiconductor device according to the first embodiment.

First, similar to the step shown in FIG. 3A of the first embodiment, as shown in FIG. 5A, a silicon wafer 11A is prepared, which includes inside, TSVs 14 of, e.g., a diameter of about 5 μm, and includes on one surface, a device layer 15 electrically connected to the TSVs 14.

Next, similar to the step shown in FIG. 3B of the first embodiment, as shown in FIG. 5B, the carrier 50 is bonded to the one surface of the silicon wafer 11A with the device layer 15 interposed therebetween.

Then, similar to the step shown in FIG. 3C of the first embodiment, as shown in FIG. 5C, the surface (hereinafter referred to as “the other surface”) of the silicon wafer 11A opposite to the carrier 50 is polished until the TSVs 14 are exposed. The thickness of the silicon wafer 11A after the polishing is, for example, about 20 μm.

Next, as shown in FIG. 5D, a photosensitive resin 51 made of, for example, photosensitive polyimide, is applied around top die mounting regions on the polished other surface of the silicon wafer 11A to be spaced apart from the mounting regions, and the photosensitive resin 51 is cured. After that, in order to reduce degradation in chip-to-chip bonding caused by the development and curing of the photosensitive resin 51, or the like, for example, oxygen plasma processing is performed to clean the polished other surface of the silicon wafer 11A which servers as top die mounting regions. The photosensitive resin 51 is applied to have a reverse pattern of the top dies 12 (see FIG. 5E) to be mounted on the silicon wafer 11A in a subsequent step. The width of the photosensitive resin 51 is adjusted so that the distance between the photosensitive resin 51 and each of the top dies 12 to be mounted on the silicon wafer 11A in the subsequent step is, for example, about 2 μm. Note that the thickness of the photosensitive resin 51 after the curing is about 100 μm, which is equal to the chip thickness of the top dies 12 to be mounted on the silicon wafer 11A in the subsequent step. FIG. 5I illustrates that the photosensitive resin 51 is provided around the top die mounting regions on the silicon wafer 11A.

In this variation, the distance between each of the top dies 12 and the photosensitive resin 51 is extremely short as compared to the first variation of the first embodiment for the following reason. Specifically, in this variation, the photosensitive resin 51 is applied to the top of the silicon wafer 11A in advance without the top dies 12, and thus, the thickness of the photosensitive resin 51 after the application can be uniform over the entire surface of the wafer. Thus, the distance between the photosensitive resin 51 and each of the top dies 12 to be mounted on the silicon wafer 11A in the subsequent step can be small in the range not affecting the bonding of the top dies 12.

After that, as shown in FIG. 5E, a plurality of top dies 12, each of which is processed in a separate chip and includes a device layer 16 on one surface, are bonded to the top die mounting regions of the polished other surface of the silicon wafer 11A, which are surrounded by the photosensitive resin 51, with the device layers 16 interposed therebetween. An uppermost layer interconnect (not shown) including an electrode pad is formed on the uppermost surface of the device layer 16. Each of the top dies 12 and the silicon wafer 11A are bonded together so that the electrode pad is electrically connected to the TSV 14 of the silicon wafer 11A. Note that the chip thickness of the top dies 12 is, for example, about 100 μm. FIG. 5J illustrates that one of the top dies 12 is bonded to the top die mounting region of the polished other surface of the silicon wafer 11A, which is surrounded by the photosensitive resin 51.

Next, as shown in FIG. 5F, the resin 13 made of, for example, polyimide, is applied on the polished other surface of the silicon wafer 11A to cover the top dies 12 and the photosensitive resin 51 formed between the adjacent top dies 12, and then cured. As a result, the gap between each of the top dies 12 and the photosensitive resin 51 is filled with the resin 13. The thickness of the resin 13 after the curing is, for example, about 50 μm on the top dies 12 and the photosensitive resin 51.

Then, as shown in FIG. 5G, the cured resin 13, the cured photosensitive resin 51, the silicon wafer 11A, and the carrier 50 are diced at once, thereby forming a plurality of double-chip structures, one of which is shown in FIG. 5G. Each of the structures includes a bottom die 11 divided from the silicon wafer 11A and being larger than a top die 12, the top die 12 bonded to the top of the bottom die 11, the resin 13 formed on the bottom die 11 to cover the top die 12, and the photosensitive resin 51 formed around the top die 12 on the bottom die 11.

After that, as shown in FIG. 5H, the carrier 50 bonded to the bottom die 11 of each of the double-chip structures is removed, thereby completing the multilayer chip of the bottom die 11 and the top die 12.

Through the above-described manufacturing process, the resin 13 and the photosensitive resin 51 can be provided in the region without the chip around the chip (i.e., the top die 12) smaller than the adjacent large chip (i.e., the bottom die 11). This structure allows the resin 13 and the photosensitive resin 51 to receive stress applied on the protrusions of the bottom die 11 from the top die 12. This leads to reduction in the local stress application on the bottom die 11, for example, the local stress application on the portions of the bottom die 11, which are in contact with the ends of the top die 12. As a result, a highly reliable semiconductor device with reduced chipping, cracks, etc. can be provided.

In this variation, the photosensitive resin 51 applied to have the reverse pattern of the top dies 12 can be used as a template in mounting the top dies 12 on the silicon wafer 11A. Since the alignment accuracy of lithography for patterning the photosensitive resin 51 is about 0.1 μm or less, the top dies 12 and the silicon wafer 11A, i.e., the bottom dies 11 can be aligned with high accuracy in this variation.

In this variation, since the photosensitive resin 51 is applied to have the reverse pattern of the top dies 12, the flatness of the resin can be further improved, thereby providing a more highly reliable semiconductor device. This technique is advantageous in stacking three or more layers of chips.

In this variation, since the resin 13 and the photosensitive resin 51 are scribed to divide into the chips, i.e., scribe lines are opened, dicing damages can be reduced. In particular, a combination of this method and for example, Cu band etching, in which TSVs filled with Cu are etched to open scribe lines, further reduces the damages.

While in this variation, an example has been described where the other surface (i.e., the surface opposite to the device layer formation surface) of the silicon wafer 11A is bonded to the device layer formation surface of each of the top dies 12, the structure is not limited thereto. The device layer formation surface of the silicon wafer 11A may be bonded to the surface of the top die 12 opposite to the device layer formation surface thereof. Alternatively, the device layer formation surfaces of the silicon wafer 11A and the top die 12, or the surfaces of the silicon wafer 11A and the top die 12 opposite to the device layer formation surfaces thereof may be bonded together.

While in this variation, the photosensitive resin 51 and the resin (coating material) 13 are made of polyimide, the material is not limited thereto. The photosensitive resin 51 and the resin 13 may be made of, for example, one or more photosensitive materials and coating materials selected from the group consisting of polyimide, acrylate monomer, epoxy acrylate, urethane acrylate, polyester acrylate, alicyclic epoxy, vinyl ether, hybrid monomer, etc.

While in this variation, the silicon wafer 11A is used as the substrate of the bottom die 11, a substrate made of other materials may be used instead.

While in this variation, the resin 13 is applied to cover the top dies 12 and the photosensitive resin 51, the configuration is not limited thereto. As long as the resin 13 is applied to fill the gaps between the top dies 12 and the photosensitive resin 51, advantages similar to those in this variation can be obtained. In this case, in the dicing shown in FIG. 5G, one of the photosensitive resin 51 or the resin 13 is diced together with the silicon wafer 11A and the carrier 50, thereby forming a double-chip structure including the bottom die 11, the top die 12 bonded to the top of the bottom die 11, and the photosensitive resin 51 and the resin 13, which are formed on the surface of the bottom die 11 closer to the top die 12 in the portion of the bottom die 11 located outside the top die 12.

### Second Embodiment

A semiconductor device and a method of manufacturing the device according to a second embodiment will be described hereinafter with reference to the drawings.

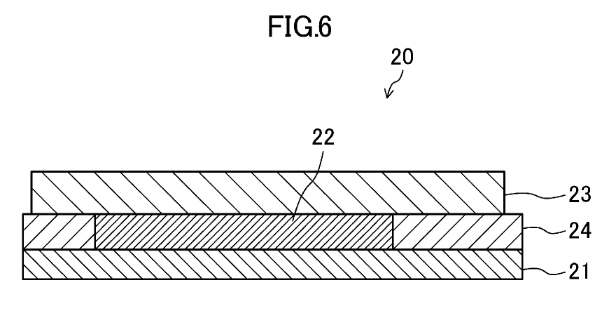

FIG. 6 is a cross-sectional view of the semiconductor device according to the second embodiment, specifically, a semiconductor device having a three-dimensional triple-chip structure.

As shown in FIG. 6, a semiconductor device 20 according to the second embodiment includes a logic chip (bottom die) 21 having, for example, a chip size of 5 mm×5 mm and a chip thickness of about 20 μm, a logic chip (middle die) 22 formed on the bottom die 21 and having, for example, a chip size of 2 mm×3 mm and a chip thickness of about 20 μm, and a DRAM chip (top die) 23 formed on the middle die 22 and having, for example, a chip size of 4 mm×4 mm and a chip thickness of about 100 μm.

The present inventor found that local stress is applied to a large chip in a stack of a plurality of chips of different sizes as in the semiconductor device shown in FIG. 6. In particular, in a multi-chip structure of a small chip and a large chip, which are adjacent in the stacking direction, excessive local stress is applied to protrusions of the large chip where the lengths of the protrusion of the large chip from the chip ends of the small chip are greater than the thickness of the large chip.

In this embodiment, a resin (specifically, photosensitive resin) 24 made of, for example, polyimide is provided around the middle die 22, i.e., in the region around the middle die 22 interposed between the bottom die 21 and the top die 23. Specifically, the resin 24 is provided on the surface of the bottom die 21 closer to the middle die 22 in the portion of the bottom die 21 located outside the middle die 22, from the tops of the ends of the bottom die 21 to the side end surfaces of the middle die 22, to be in contact with the surface of the top die 23 closer to the middle die 22 in the portion of the top die 23 located outside the middle die 22. The side end surfaces of the bottom die 21 of the largest size are substantially flush with the side end surfaces of the resin 24.

In this embodiment, the resin 24 is provided in the region without the chip around the chip (i.e., the middle die 22) smaller than the adjacent chips (i.e., the bottom die 21 and the top die 23). This structure allows the resin 24 to receive stress applied on the protrusions of the bottom die 21 and the top die 23 from the middle die 22. This leads to reduction in local stress application on the bottom die 21 and the top die 23, for example, local stress application on the portions of the bottom die 21, which are in contact with the ends of the middle die 22, and on the portions of the top die 23, which are in contact with the ends of the middle die 22. As a result, a highly reliable semiconductor device with reduced chipping, cracks, etc. can be provided.

While in this embodiment, an example has been described where a logic chip and a DRAM chip are stacked, the present disclosure is not limited thereto. Where other types of chip with various functions are stacked, advantages similar to those of this embodiment can be provided. In this embodiment, the triple-chip structure has been described as an example. Instead, where the multi-chip structure is formed of four or more layers, advantages similar to those of this embodiment can be provided.

While in this embodiment, the resin 24 is provided on the ends of the bottom die 21, the resin 24 may not be provided on the ends of the bottom die 21. While the resin 24 is provided in contact with the side end surfaces of the middle die 22, the resin 24 may be spaced apart from the side end surfaces of the middle die 22. While the resin 24 is provided so that the side end surfaces of the resin 24 are substantially flush with the side end surfaces of the bottom die 21, the resin 24 may be provided so that the side end surfaces of the resin 24 are not flush with the side end surfaces of the bottom die 21.

While in this embodiment, the resin 24 is made of polyimide, the material is not limited thereto. The resin 24 may be made of, for example, one or more materials selected from the group consisting of polyimide, acrylate monomer, epoxy acrylate, urethane acrylate, polyester acrylate, alicyclic epoxy, vinyl ether, hybrid monomer, etc.

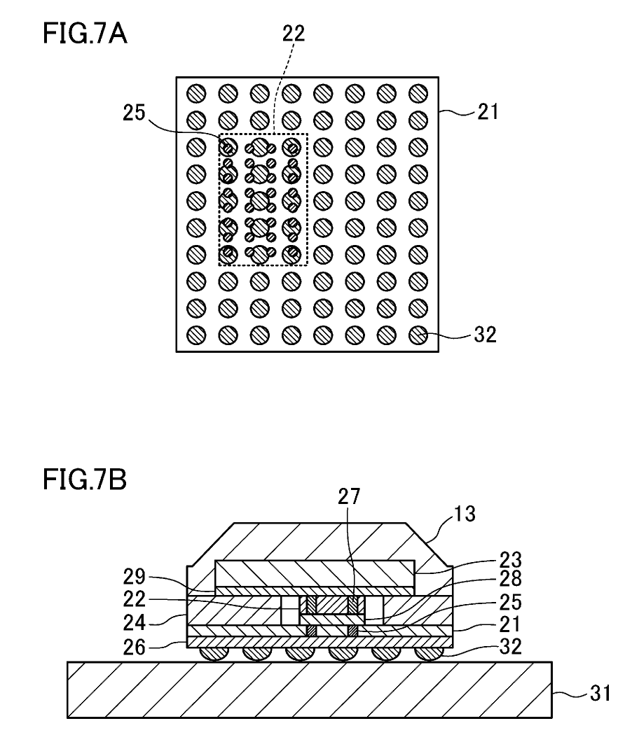

FIGS. 7A and 7B are respectively a top view and a cross-sectional view illustrating an example where a semiconductor device having a multi-chip structure similar to that of this embodiment is mounted on a printed-circuit board. FIG. 7A illustrates the surface of the semiconductor device, which is mounted on the printed-circuit board, together with the mounting range of the small chip (i.e., the middle die) and a through electrode of a large chip (i.e., the bottom die, a device layer is not shown) located in the range. In FIGS. 7A and 7B, the same reference characters as those shown in FIG. 6 are used to represent elements corresponding to the elements of the semiconductor device according to this embodiment.

As shown in FIGS. 7A and 7B, the middle die 22 having a small area and a small chip thickness, and the top die 23 having a large area and a great chip thickness are sequentially stacked on the bottom die 21 having a large area and a small chip thickness, thereby forming a triple-layer chip. Through electrodes 25 are formed in the bottom die 21. A device layer 26 electrically connected to the through electrodes 25 is provided on the surface of the bottom die 21 opposite to the middle die 22. Solder bumps 32 are provided on the surface of the device layer 26 opposite to the middle die 22. The triple-layer chip of the bottom die 21, the middle die 22, and the top die 23 are flip-chip mounted on a printed-circuit board 31 with the solder bumps 32 interposed therebetween.

Through electrodes 27 are formed in the middle die 22. A device layer 28 electrically connected to the through electrodes 25 is provided on the surface of the middle die 22 closer to the bottom die 21.

A device layer 29 electrically connected to the through electrodes 27 is provided on the surface of the top die 23 closer to the middle die 22.

The resin 24 is provided in the region around the middle die 22 interposed between the bottom die 21 and the top die 23. Specifically, the resin 24 is interposed between the protrusions of the bottom die 21 and the top die 23 from the middle die 22. This enables high-density mounting of a semiconductor device with reduced chipping, cracks, etc.

While in the mounting example shown in FIGS. 7A and 7B, the triple-layer chip is flip-chip mounted on the printed-circuit board 31, an interposer (e.g., an interposing substrate), a silicon interposer (e.g., a silicon interposing substrate), etc. may be used in place of the printed-circuit board 31.

A method of manufacturing the semiconductor device according to the second embodiment, and more particularly, a method of manufacturing a semiconductor device having a structure similar to that of the semiconductor device according to the second embodiment shown in FIG. 6 will be described hereinafter with reference to the drawings.

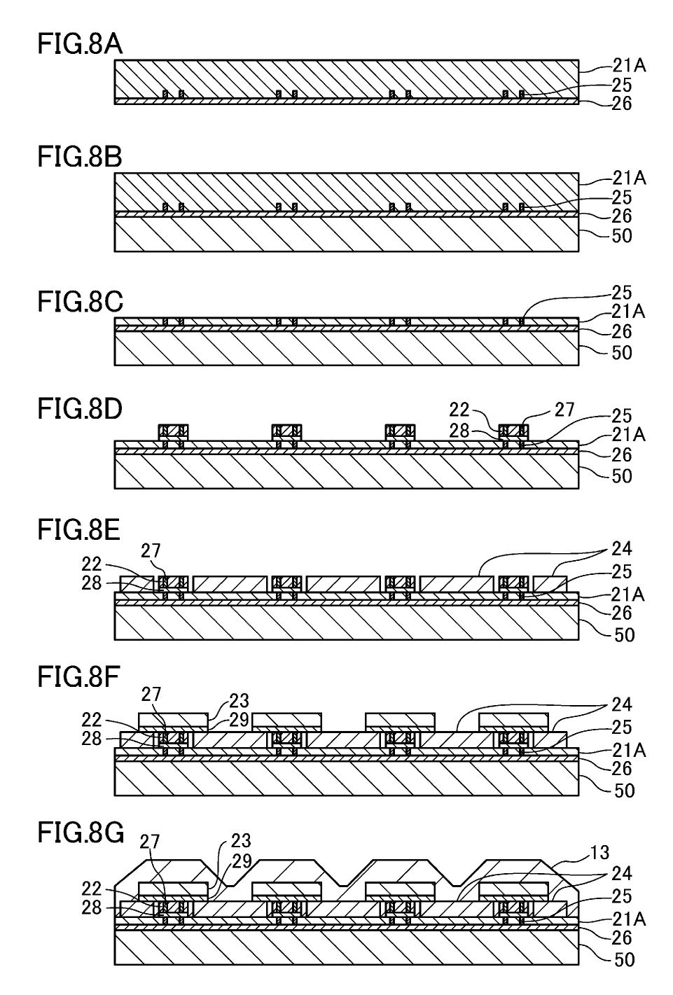

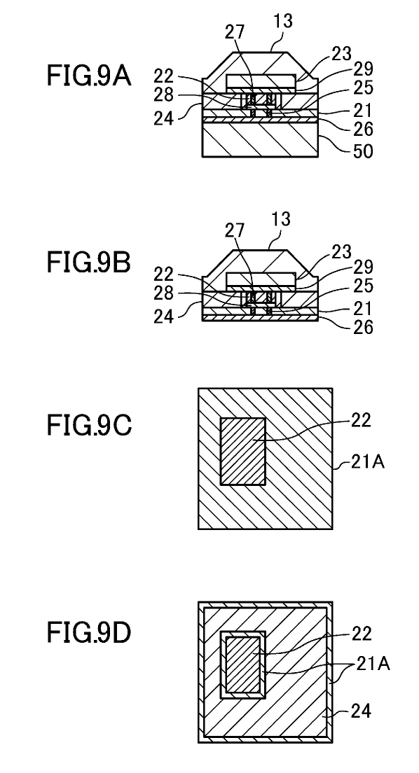

FIGS. 8A-8G, 9A, and 9B are cross-sectional views illustrating steps of the method of manufacturing the semiconductor device according to the second embodiment. FIG. 9C is a top view corresponding to the cross-sectional view of FIG. 8D. FIG. 9D is a top view corresponding to the cross-sectional view of FIG. 8E. In FIGS. 8A-8G and 9A-9D, the same reference characters as those shown in FIGS. 6, 7A, and 7B are used to represent elements corresponding to the elements of the semiconductor device according to this embodiment.

First, as shown in FIG. 8A, a silicon wafer 21A is prepared, which includes inside, through electrodes (TSV) 25 with a diameter of, e.g., about 5 μm, and includes on one surface, a device layer 26 electrically connected to the TSVs 25.

Next, as shown in FIG. 8B, a carrier 50 is bonded to the one surface of the silicon wafer 21A with the device layer 26 interposed therebetween.

Then, as shown in FIG. 8C, the surface (hereinafter referred to as “the other surface”) of the silicon wafer 21A opposite to the carrier 50 is polished until the TSVs 25 are exposed. The thickness of the silicon wafer 21A after the polishing is, for example, about 20 μm.

After that, as shown in FIG. 8D, the plurality of middle dies 22, each of which is processed in a separate chip and includes the device layer 28 on one surface, are bonded to the polished other surface of the silicon wafer 21A with the device layers 28 interposed therebetween. Each of the middle dies 22 includes through electrodes (TSVs) 27 penetrating the substrate of the middle die 22. An uppermost layer interconnect (not shown) including an electrode pad electrically connected to the TSV 27 is formed on the uppermost surface of the device layer 28. Each of the middle dies 22 and the silicon wafer 21A are bonded together so that the electrode pad is electrically connected to the TSV 25 of the silicon wafer 21A. Note that the middle dies 22 are polished in advance so that the TSVs 27 are exposed to the surface opposite to the device layer formation surface thereof, and have a chip thickness of, e.g., about 20 μm. FIG. 9C illustrates that one of the middle dies 22 is bonded to the polished other surface of the silicon wafer 21A.

Next, as shown in FIG. 8E, a photosensitive resin 24 made of, for example, photosensitive polyimide, is applied around the middle dies 22 on the silicon wafer 21A to be spaced apart from the middle dies 22, and then the photosensitive resin 24 is cured. The photosensitive resin 24 is applied to have a reverse pattern of the middle dies 22. The distance between the photosensitive resin 24 and each of the middle dies 22 in the application is, for example, about 10 μm. The thickness of the photosensitive resin 24 after the curing is about 18 μm, which is slightly smaller than the chip thickness of the middle dies 22. The thickness of the photosensitive resin 24 is made slightly smaller than the chip thickness of the middle dies 22 for the following reason. Specifically, if the thickness of the photosensitive resin 24 is greater than the chip thickness of the middle dies 22, the middle dies 22 and the top dies 23 (see FIG. 8F) cannot be bonded together, or the bond strength between the dies is reduced. In order to avoid the situations, the thickness of the photosensitive resin 24 after the curing is formed slightly smaller than the chip thickness of the middle dies 22 in view of process variations in the chip thickness of the middle dies 22, the thickness of the photosensitive resin 24, etc. FIG. 9D illustrates that the photosensitive resin 24 is provided around one of the middle dies 22 bonded to the silicon wafer 21A.

Then, as shown in FIG. 8F, the plurality of top dies 23, each of which is processed in a separate chip and including the device layer 29 on one surface, are bonded to the surfaces of the plurality of middle dies 22 opposite to the device layer formation surfaces thereof with the device layers 29 interposed therebetween. An uppermost layer interconnect (not shown) including an electrode pad is formed on the uppermost surface of the device layer 29. Each of the top dies 23 and the corresponding middle die 22 are bonded together so that the electrode pad is electrically connected to the TSV 27 of the middle die 22. Note that the top dies 23 have a chip thickness of, e.g., about 100 μm. The top dies 23 have a larger size (i.e., area) than the middle dies 22. The top dies 23 are provided so that protrusions of the top dies 23 from the middle dies 22 cover the photosensitive resin 24. Although not shown, space occurs between the photosensitive resin 24 formed around the middle dies 22 and having a slightly smaller thickness than the chip thickness of the middle dies 22, and the portions of the tops dies 23 located above the photosensitive resin 24, by the difference between the thickness of the middle dies 22 and the thickness of the photosensitive resin 24.

Next, as shown in FIG. 8G, the resin 13 made of, for example, polyimide, is applied on the polished other surface of the silicon wafer 21A to cover the top dies 23 and the photosensitive resin 24, and then cured. The thickness of the resin 13 after the curing is, for example, about 50 μm. Note that the resin 13 enters the space between the photosensitive resin 24 and the portions of the top dies 23 located above the photosensitive resin 24 in the application of the resin 13. As a result, the photosensitive resin 24 comes into contact with the top dies 23 with the resin 13 interposed therebetween, thereby reinforcing the bond strength between the top dies 23 and the bottom dies 21 (see FIG. 9A).

Then, as shown in FIG. 9A, the cured resin 13, the cured photosensitive resin 24, the silicon wafer 21A, and the carrier 50 are diced at once, thereby forming a plurality of triple-chip structures, one of which is shown in FIG. 9A. Each of the structures includes a bottom die 21 divided from the silicon wafer 21A and being larger than the middle die 22 and the top die 23, the middle die 22 bonded to the top of the bottom die 21, the top die 23 bonded to the top of the middle die 22, and the photosensitive resin 24 formed around the middle die 22 interposed between the bottom die 21 and the top die 23.

After that, as shown in FIG. 9B, the carrier 50 bonded to the bottom die 21 of each of the triple-chip structures is removed, thereby completing the multilayer chip of the bottom die 21, the middle die 22, and the top die 23.

Through the above-described manufacturing process, the photosensitive resin 24 can be provided in the region without the chip around the smaller chip (i.e., the middle die 22) interposed between the two adjacent larger chips (i.e., the bottom die 21 and the top die 23). This structure allows the photosensitive resin 24 to receive stress applied on the protrusions of the bottom die 21 and the top die 23 from the middle die 22. This leads to reduction in the local stress application on the bottom die 21 and the top die 23, for example, the local stress application on the portions of the bottom die 21, which are in contact with the ends of the middle die 22, and on the portions of the top die 23, which are in contact with the ends of the middle die 22. As a result, a highly reliable semiconductor device with reduced chipping, cracks, etc. can be provided.

In this embodiment, the pattern of the photosensitive resin 24 is formed after stacking the middle die 22 on the silicon wafer 21A which servers as the bottom die 21. This reduces degradation in chip-to-chip bonding caused by the development and curing of the photosensitive resin 24.

In this embodiment, since the photosensitive resin 24 is applied to have the reverse pattern of the middle dies 22, the flatness of the resin can be further improved, thereby providing a more highly reliable semiconductor device. This technique is advantageous in stacking three or more layers of chips.

In this embodiment, since the photosensitive resin 24 is scribed and divided into the chips, i.e., scribe lines are opened, dicing damages can be reduced. In particular, a combination of this method and for example, Cu band etching, in which TSVs filled with Cu are etched to open scribe lines, further reduces the damages.

In this embodiment, an example has been described where the other surface (i.e., the surface opposite to the device layer formation surface) of the silicon wafer 21A is bonded to the device layer formation surface of each of the middle dies 22, and the surface of the middle die 22 opposite to the device layer formation surface thereof, is bonded to the device layer formation surface of the top die 23. However, the structure is not limited thereto. The device layer formation surface of the silicon wafer 21A may be bonded to the surface of the middle die 22 opposite to the device layer formation surface thereof. Alternatively, the device layer formation surfaces of the silicon wafer 21A and the middle die 22, or the surfaces of the silicon wafer 21A and the middle die 22 opposite to the device layer formation surfaces thereof may be bonded together. The device layer formation surface of the middle die 22 may be bonded to the surface of the top die 23 opposite to the device layer formation surface thereof. Alternatively, the device layer formation surfaces of the middle die 22 and the top die 23 or the surfaces of the middle die 22 and the top die 23 opposite to the device layer formation surfaces thereof may be bonded together.

While in this embodiment, the triple-chip structure has been described as an example, instead, a multi-chip structure of four or more layers provides advantages similar to those of this embodiment.

While in this embodiment, the photosensitive resin 24 is made of polyimide, the material is not limited thereto. The photosensitive resin 24 may be made of, for example, one or more materials selected from the group consisting of polyimide, acrylate monomer, epoxy acrylate, urethane acrylate, polyester acrylate, alicyclic epoxy, vinyl ether, hybrid monomer, etc.

While in this embodiment, the silicon wafer 21A is used as the substrate of the bottom die 21, a substrate made of other materials may be used instead.

While in this embodiment, the resin 13 is made of polyimide, the material is not limited thereto. The resin 13 may be made of, for example, one or more materials selected from the group consisting of polyimide, acrylate monomer, epoxy acrylate, urethane acrylate, polyester acrylate, alicyclic epoxy, vinyl ether, hybrid monomer, etc. The resin 13 may or may not fill the gap between each of the middle die 22 and the photosensitive resin 24.

### Variation of Second Embodiment

A method of manufacturing a semiconductor device according to a variation of the second embodiment, and more particularly, a method of manufacturing a semiconductor device having a structure similar to that of the semiconductor device according to the second embodiment shown in FIG. 6 will be described hereinafter with reference to the drawings.

This variation differs from the second embodiment in the following respect. Specifically, in the second embodiment, after the middle dies 22 and the silicon wafer 21A are bonded together, the photosensitive resin 24 is formed around the middle dies 22 on the silicon wafer 21A. On the other hand, in this variation, after the photosensitive resin is formed around the middle die mounting regions on the silicon wafer, the middle dies and the silicon wafer are bonded together.

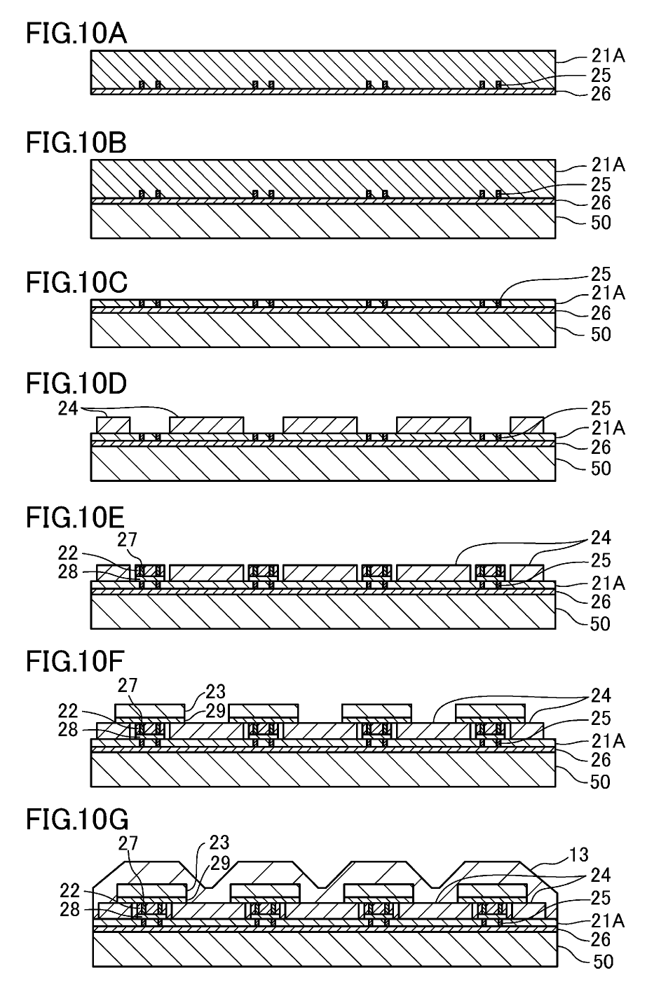

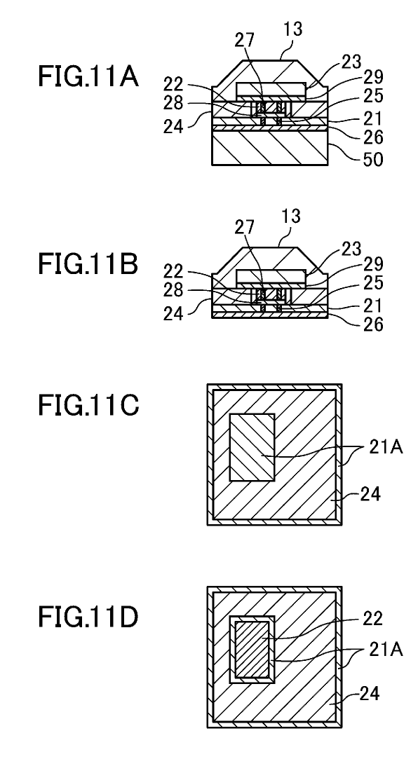

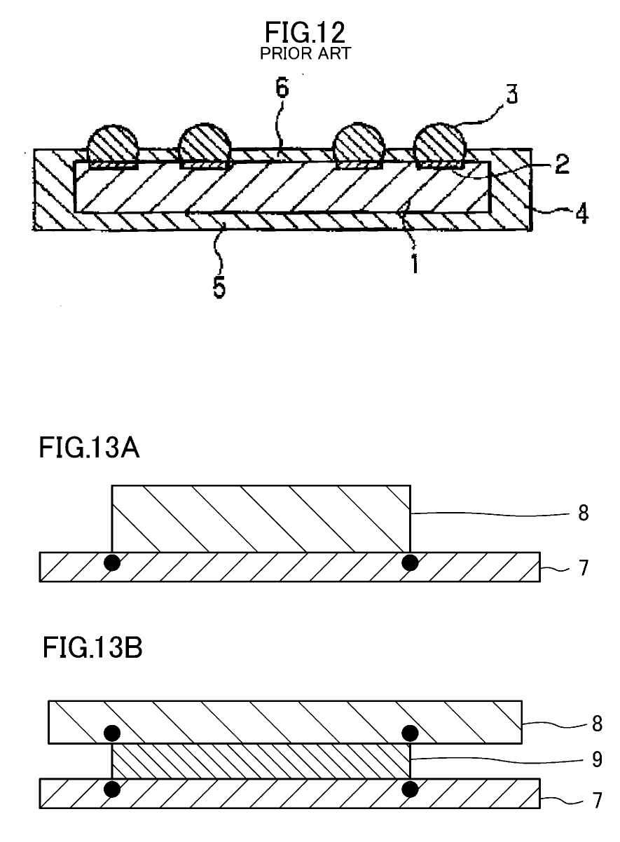

FIGS. 10A-10G, 11A, and 11B are cross-sectional views illustrating steps of the method of manufacturing the semiconductor device according to the variation of the second embodiment. FIG. 11C is a top view illustrating the step of FIG. 10D. FIG. 11D is a top view illustrating the step of FIG. 10E. In FIGS. 10A-10G and 11A-11D, the same reference characters as those shown in FIGS. 6, 7A and 7B are used to represent elements corresponding to the elements of the semiconductor device according to the second embodiment.

First, similar to the step shown in FIG. 8A of the second embodiment, as shown in FIG. 10A, a silicon wafer 21A is prepared, which includes inside, TSVs 25 of, e.g., a diameter of about 5 μm, and includes on one surface, a device layer 26 electrically connected to the TSVs 25.

Next, similar to the step shown in FIG. 8B of the second embodiment, as shown in FIG. 10B, the carrier 50 is bonded to the one surface of the silicon wafer 21A with the device layer 26 interposed therebetween.

Then, similar to the step shown in FIG. 8C of the second embodiment, as shown in FIG. 10C, the surface (hereinafter referred to as “the other surface”) of the silicon wafer 21A opposite to the carrier 50 is polished until the TSVs 25 are exposed. The thickness of the silicon wafer 21A after the polishing is, for example, about 20 μm.

Next, as shown in FIG. 10D, a photosensitive resin 24 made of, for example, photosensitive polyimide, is applied around middle die mounting regions on the polished other surface of the silicon wafer 21A to be spaced apart from the mounting regions, and the photosensitive resin 24 is then cured. After that, in order to reduce degradation in chip-to-chip bonding caused by the development and curing of the photosensitive resin 24, or the like, for example, oxygen plasma processing is performed to clean the polished other surface of the silicon wafer 21A which servers as top die mounting regions. The photosensitive resin 24 is applied to have a reverse pattern of the middle dies 22 (see FIG. 10E) to be mounted on the silicon wafer 21A in a subsequent step. The width of the photosensitive resin 24 is adjusted so that the distance between the photosensitive resin 24 and each of the middle dies 22 to be mounted on the silicon wafer 21A in the subsequent step is, for example, about 2 μm. The thickness of the photosensitive resin 24 after the curing is about 18 μm, which is slightly smaller than the chip thickness of the middle dies 22 to be mounted on the silicon wafer 21A in the subsequent step. The thickness of the photosensitive resin 24 is formed slightly smaller than the chip thickness of the middle dies 22 for the following reason. Specifically, if the thickness of the photosensitive resin 24 is greater than the chip thickness of the middle dies 22, the middle dies 22 and top dies 23 (see FIG. 10F) cannot be bonded together, or the bond strength between the dies is reduced. In order to avoid the situations, the thickness of the photosensitive resin 24 after the curing is formed slightly smaller than the chip thickness of the middle dies 22 in view of process variations of the chip thickness of the middle dies 22, the thickness of the photosensitive resin 24, etc. FIG. 11C illustrates that the photosensitive resin 24 is provided around the middle die mounting regions on the silicon wafer 21A.

In this variation, the distance between each of the middle dies 22 and the photosensitive resin 24 is extremely short as compared to the second embodiment for the following reason. Specifically, in this variation, the photosensitive resin 24 is applied to the silicon wafer 21A in advance without the middle dies 22, and thus, the thickness of the photosensitive resin 24 after the application can be uniform over the entire surface of the wafer. Thus, the distance between the photosensitive resin 24 and each of the middle dies 22 to be mounted on the silicon wafer 21A in the subsequent step can be small in the range not affecting the bonding of the middle die 22.

After that, as shown in FIG. 10E, the plurality of middle dies 22, each of which is processed in a separate chip and includes a device layer 28 on one surface, are bonded to the middle die mounting regions surrounded by the photosensitive resin 24 on the polished other surface of the silicon wafer 21A with the device layers 28 interposed therebetween. Each of the middle dies 22 includes TSV 27 penetrating the substrate of the middle die 22. An uppermost layer interconnect (not shown) including an electrode pad electrically connected to the TSV 27 is formed on the uppermost surface of the device layer 28. Each of the middle dies 22 and the silicon wafer 21A are bonded together so that the electrode pad is electrically connected to each of the TSV 25 of the silicon wafer 21A. Note that the middle dies 22 are polished in advance so that the TSVs 27 are exposed to the surface opposite to the device layer formation surface, and have a chip thickness of, e.g., about 20 μm. FIG. 11D illustrates that one of the middle dies 22 is bonded to the middle die mounting region surrounded by the photosensitive resin 24 on the polished other surface of the silicon wafer 21A.

After that, as shown in FIG. 10F, the plurality of top dies 23, each of which is processed in a separate chip and includes a device layer 29 on one surface thereof, are bonded to the surfaces of the middle dies 22 opposite to the device layer formation surfaces, with the device layers 29 interposed therebetween. An uppermost layer interconnect (not shown) including an electrode pad is formed on the uppermost surface of the device layer 29. Each of the top dies 23 and the corresponding middle dies 22 are bonded together so that the electrode pad is electrically connected to the TSV 27 of the middle die 22. Note that the top dies 23 have a chip thickness of, e.g., about 100 μm. The top dies 23 have a larger size (i.e., area) than the middle dies 22. The top dies 23 are provided so that protrusions of the top dies 23 from the middle dies 22 cover the photosensitive resin 24. Although not shown, space occurs between the photosensitive resin 24 formed around the middle dies 22 and having a slightly smaller thickness than the chip thickness of the middle dies 22, and the portions of the tops dies 23 located above the photosensitive resin 24, by the difference between the thickness of the middle dies 22 and the thickness of the photosensitive resin 24.

Next, as shown in FIG. 10G, a resin 13 made of, for example, polyimide, is applied on the polished other surface of the silicon wafer 21A to cover the top dies 23 and the photosensitive resin 24, and then cured. The thickness of the resin 13 after the curing is, for example, about 50 μm. Note that the resin 13 enters the space between the photosensitive resin 24 and the portions of the top dies 23 located above the photosensitive resin 24 in the application of the resin 13. As a result, the photosensitive resin 24 comes into contact with the top dies 23 with the resin 13 interposed therebetween, thereby reinforcing the bond strength between the top dies 23 and the bottom dies 21 (see FIG. 11A).

Then, as shown in FIG. 11A, the cured resin 13, the cured photosensitive resin 24, the silicon wafer 21A, and the carrier 50 are diced at once, thereby forming a plurality of triple-chip structures, one of which is shown in FIG. 11A. Each of the structures includes a bottom die 21 divided from the silicon wafer 21A and being larger than the middle die 22 and the top die 23, the middle die 22 bonded to the top of the bottom die 21, the top die 23 bonded to the top of the middle die 22, and the photosensitive resin 24 formed around the middle die 22 interposed between the bottom die 21 and the top die 23.

After that, as shown in FIG. 11B, the carrier 50 bonded to the bottom die 21 of each of the triple-chip structures is removed, thereby completing the multilayer chip of the bottom die 21, the middle die 22, and the top die 23.

Through the above-described manufacturing process, the photosensitive resin 24 can be provided in the region without the chip around the smaller chip (i.e., the middle die 22) interposed between two adjacent larger chips (i.e., the bottom die 21 and the top die 23). This structure allows the photosensitive resin 24 to receive stress applied on the protrusions of the bottom die 21 and the top die 23 from the middle die 22. This leads to reduction in the local stress application on the bottom die 21 and the top die 23, for example, the local stress application on the portions of the bottom die 21, which are in contact with the ends of the middle die 22, and on the portions of the top die 23, which are in contact with the ends of the middle die 22. As a result, a highly reliable semiconductor device with reduced chipping, cracks, etc. can be provided.

In this variation, the photosensitive resin 24 applied to have the reverse pattern of the middle dies 22 can be used as a template in mounting the middle dies 22 on the silicon wafer 21A. Since the alignment accuracy of lithography for patterning the photosensitive resin 24 is about 0.1 μm or less, the middle dies 22 and the silicon wafer 21A, i.e., the bottom dies 21 can be aligned with high accuracy in this variation.

In this variation, since the photosensitive resin 24 is applied to have the reverse pattern of the middle dies 22, the flatness of the resin can be further improved, thereby providing a more highly reliable semiconductor device. This technique is advantageous in stacking three or more layers of chips.

In this variation, since the photosensitive resin 24 is scribed and divided into the chips, i.e., scribe lines are opened, dicing damages can be reduced. In particular, a combination of this method and for example, Cu band etching, in which TSVs filled with Cu are etched to open scribe lines, further reduces the damages.

In this variation, an example has been described where the other surface (i.e., the surface opposite to the device layer formation surface) of the silicon wafer 21A is bonded to the device layer formation surface of the middle die 22, and the surface of the middle die 22 opposite to the device layer formation surface thereof is bonded to the device layer formation surface of the top die 23. However, the structure is not limited thereto. The device layer formation surface of the silicon wafer 21A may be bonded to the surface of the middle die 22 opposite to the device layer formation surface thereof. Alternatively, the device layer formation surfaces of the silicon wafer 21A and the middle die 22, or the surfaces of the silicon wafer 21A and the middle die 22 opposite to the device layer formation surfaces thereof may be bonded together. The device layer formation surface of the middle die 22 may be bonded to the surface of the top die 23 opposite to the device layer formation surface thereof. Alternatively, the device layer formation surfaces of the middle die 22 and the top die 23 or the surfaces of the middle die 22 and the top die 23 opposite to the device layer formation surfaces thereof may be bonded together.

While in this variation, the triple-chip structure has been described as an example, instead, a multi-chip structure of four or more layers provides advantages similar to those of this embodiment.

While in this variation, the photosensitive resin 24 is made of polyimide, the material is not limited thereto. The photosensitive resin 24 may be made of, for example, one or more materials selected from the group consisting of polyimide, acrylate monomer, epoxy acrylate, urethane acrylate, polyester acrylate, alicyclic epoxy, vinyl ether, hybrid monomer, etc.

While in this variation, the silicon wafer 21A is used as the substrate of the bottom die 21, a substrate made of other materials may be used instead.

While in this variation, the resin 13 is made of polyimide, the material is not limited thereto. The resin 13 may be made of, for example, one or more materials selected from the group consisting of polyimide, acrylate monomer, epoxy acrylate, urethane acrylate, polyester acrylate, alicyclic epoxy, vinyl ether, hybrid monomer, etc. The resin 13 may or may not fill the gap between each of the middle die 22 and the photosensitive resin 24.

What is claimed is:

1. A semiconductor device having a three dimensional multi-chip structure comprising a plurality of chips stacked one on another, wherein
the three dimensional multi-chip structure includes
a first chip, and
a second chip being adjacent to the first chip on an upper or lower side of the first chip, and larger than the first chip,
a through electrode is formed in at least one of the first chip or the second chip,
the first chip is electrically connected to the second chip via the through electrode, and
a resin is provided on a surface of the second chip closer to the first chip in a portion of the second chip located outside the first chip.

2. The semiconductor device of claim 1, wherein
the through electrode is formed in the second chip,
a device layer including an electrode pad is formed on a surface of the first chip closer to the second chip, and
the first chip and the second chip are bonded together so that the through electrode of the second chip is electrically connected to the electrode pad.

3. The semiconductor device of claim 1, wherein
the resin is also formed on an end of the second chip.

4. The semiconductor device of claim 1, wherein
a side end surface of the resin is substantially flush with a side end surface of the second chip.

5. The semiconductor device of claim 1, wherein
the three dimensional multi-chip structure is a double-chip structure of the first chip and the second chip.

6. The semiconductor device of claim 5, wherein
the resin is provided to cover a surface of the first chip opposite to the second chip.

7. The semiconductor device of claim 1, wherein
the resin is provided to cover a corner formed by a side end surface of the first chip, and the surface of the second chip closer to the first chip in the portion of the second chip located outside the first chip.

8. The semiconductor device of claim 1, wherein
the resin has a substantially same thickness as the first chip.

9. The semiconductor device of claim 1, wherein
a gap is formed in at least part of space between the resin and the side end surface of the first chip.

10. The semiconductor device of claim 9, wherein
another resin different from the resin fills the gap.

11. The semiconductor device of claim 1, wherein
the three dimensional multi-chip structure further includes a third chip being adjacent to the first chip on a surface of the first chip opposite to the second chip, and larger than the first chip.

12. The semiconductor device of claim 11, wherein
a first through electrode is provided in the first chip,
a second through electrode is provided in the second chip, and
the first chip and the second chip are bonded together so that the first through electrode is electrically connected to the second through electrode.

13. The semiconductor device of claim 12, wherein
a device layer, which includes an electrode pad electrically connected to the first through electrode, is provided on a surface of the first chip closer to the second chip, and
the first chip and the second chip are bonded together so that the second through electrode of the second chip is electrically connected to the electrode pad.

14. The semiconductor device of claim 12, wherein
a device layer, which includes an electrode pad, is provided on a surface of the third chip closer to the first chip, and
the first chip and the third chip are bonded together so that the first through electrode of the first chip is electrically connected to the electrode pad.

15. The semiconductor device of claim 11, wherein
the resin is provided in contact with a surface of the third chip closer to the first chip in a portion of the third chip located outside the first chip.

16. The semiconductor device of claim 11, wherein
a gap is formed in at least part of space between the resin and the side end surface of the first chip.

17. The semiconductor device of claim 16, wherein
another resin different from the resin fills the gap.

18. The semiconductor device of claim 1, wherein
the resin is made of a material selected from the group consisting of polyimide, acrylate monomer, epoxy acrylate, urethane acrylate, polyester acrylate, alicyclic epoxy, vinyl ether, and hybrid monomer.
